(19) United States
(12) Patent Application Publication
(10) Pub. No.: US 2024/0248046 A1
(43) Pub. Date: Jul. 25, 2024

(54) MULTI-HEAD OPTICAL INSPECTION SYSTEMS AND TECHNIQUES FOR SEMICONDUCTOR MANUFACTURING

(71) Applicant: Applied Materials, Inc., Santa Clara, CA (US)

(72) Inventors: Keith Wells, Santa Clara, CA (US); Ron Naftali, Shoham (IL); Elad Eizner, Rehovot (IL); Tal Kuzniz, Rehovot (IL); Chi-Ming Tsai, Santa Clara, CA (US)

(21) Appl. No.: 18/405,546

(22) Filed: Jan. 5, 2024

Related U.S. Application Data
(60) Provisional application No. 63/440,786, filed on Jan. 24, 2023.

(51) Int. Cl. G01N 21/95; G01N 21/88

(52) U.S. Cl. CPC G01N 21/9501; G01N 21/8806; G01N 2021/8835; G01N 2021/8848; G01N 2201/025; G01N 2201/06113; G01N 2201/06146; G01N 2201/0691; G01N 2201/0697

(57) ABSTRACT

Implementations disclosed describe, among other things, a system and a method of using a wafer inspection system that includes a plurality of inspection heads configured to concurrently inspect a separate region of a plurality of regions of a wafer. Each inspection head includes an illumination subsystem to illuminate a corresponding region of the wafer, a collection subsystem to collect a portion of light reflected/scattered from the corresponding region of the wafer. Each inspection head further includes a light detection subsystem to detect the collected light and generate one or more signals representative of a state of the corresponding region of the wafer. The wafer inspection system further includes a processing device configured to determine, using the one or more signals received from each of the inspection heads, the quality of the wafer.

### RELATED APPLICATIONS

This application claims the benefit of U.S. Provisional Patent Application No. 63/440,786, filed Jan. 24, 2023, entitled “Multi-Head Optical Inspection Systems and Techniques for Semiconductor Manufacturing,” the contents of which are incorporated by reference in their entirety herein.

### TECHNICAL FIELD

This instant specification generally relates to ensuring quality control of materials manufactured in substrate processing systems. More specifically, the instant specification relates to optical inspection methods and devices for use in quality control of substrates during various stages of the manufacturing process.

### BACKGROUND

Manufacturing of modern materials often involves various deposition techniques, such as chemical vapor deposition (CVD) or physical vapor deposition (PVD) techniques, in which atoms of one or more selected types are deposited on a substrate (wafer) held in low or high vacuum environments that are provided by vacuum deposition chambers. Materials manufactured in this manner may include monocrystals, semiconductor films, fine coatings, and numerous other substances used in practical applications, such as electronic device manufacturing. Many of these applications rely on the purity of the materials grown in substrate processing systems. The need to maintain isolation of the inter-chamber environment and to minimize its exposure to ambient atmosphere and contaminants therein gives rise to various robotic techniques of sample manipulation and inspection techniques, including the use of bare wafers and bare wafer inspection to verify the performance of the equipment. Improving precision, reliability, and efficiency of such robotic techniques presents a number of technological challenges whose successful resolution facilitates continuing progress of electronic device manufacturing. This is especially applicable given that the demands to the quality of chamber manufacturing products are constantly increasing.

### BRIEF DESCRIPTION OF THE DRAWINGS

FIG. 1A illustrates an example manufacturing system capable of using an inspection device with multiple inspection heads for wafer quality control during front-end wafer manufacturing, in accordance with at least one embodiment.

FIG. 1B illustrates schematically an example manufacturing line that performs bare wafer manufacturing and uses an optical inspection device with multiple inspection heads for wafer quality control, in accordance with at least one embodiment.

FIG. 2A illustrates one example multi-head optical inspection system, in accordance with at least one embodiment.

FIG. 2B illustrates another example multi-head optical inspection system, in accordance with at least one embodiment.

FIG. 2C illustrates yet another example multi-head optical inspection system, in accordance with at least one embodiment.

FIGS. 3A-D illustrate schematically example operations of a movable stage that imparts motion to a wafer under inspection, in accordance with some embodiments.

FIG. 4 is a flow diagram of an example method of optical inspection of a wafer performed using multi-head inspection apparatus, in accordance with at least one embodiment.

FIG. 5 depicts a block diagram of an example computing device operating in accordance with one or more aspects of the present disclosure.

### SUMMARY

Some of the embodiments described herein are related to a wafer inspection system that includes a plurality of inspection heads. Each of the plurality of inspection heads is configured to inspect a corresponding region of a plurality of regions of a wafer. Individual inspection head includes an illumination subsystem configured to illuminate, with a beam of light, a corresponding region of the wafer. Individual inspection head further includes a collection subsystem configured to collect a portion of light generated upon interaction of the beam of light with the corresponding region of the wafer. Individual inspection head further includes a light detection subsystem configured to detect the collected light and generate one or more signals representative of a state of the corresponding region of the wafer. The wafer inspection system further includes a processing device configured to determine, using the one or more signals received from each of the plurality of inspection heads, a quality of the wafer.

Another embodiment described herein is related to another wafer inspection system that includes a first inspection head configured to inspect a first region of a wafer. The first inspection head includes a first illumination subsystem configured to illuminate the first region with a first normally-incident light and a first obliquely-incident light. The first inspection head further includes a first collection subsystem configured to collect a first reflected light, wherein the first reflected light is generated upon interaction of the first normally-incident light with the first region, and a first scattered light, wherein the first scattered light is generated upon interaction of at least one of the first normally-incident light or the first obliquely-incident light with the first region. The first inspection head further includes a first light detection subsystem configured to generate, using the first reflected light and the first scattered light, one or more first signals representative of a quality of the first region. The wafer inspection system includes a second inspection head configured to inspect a second region of the wafer concurrently with the first inspection head inspecting the first region of the wafer. The second inspection head includes a second illumination subsystem configured to illuminate the second region with a second normally-incident light and a second obliquely-incident light. The second collection subsystem is configured to collect a second reflected light, wherein the second reflected light is generated upon interaction of the second normally-incident light with the second region, and a second scattered light, wherein the second scattered light is generated upon interaction of at least one of the second normally-incident light or the second obliquely-incident light with the second region. The second inspection head includes a second light detection subsystem configured to generate, using the second reflected light and the second scattered light, one or more second signals representative of a quality of the second region. The wafer inspection system further includes a processing device configured to determine, using the one or more first signals and the one or more second signals, a quality of the wafer.

Another embodiment described is related to a method to perform an optical inspection of a wafer. The method includes illuminating a plurality of regions of a wafer, each region of the plurality of regions illuminated by a respective illumination subsystem of a plurality of illumination subsystems. The method further includes collecting a plurality of portions of light, each of the plurality of portions of light collected by a respective collection subsystem of a plurality of collection subsystems. The method further includes detecting the collected plurality of portions of light, each collected portion of light of the plurality of collected portions of light detected by a respective detection subsystem of a plurality of detection subsystems. The method further includes generating a plurality of signals, each signal of the plurality of signals generated using a respective collected portion of light of the plurality of collected portions of light. The method further includes determining, using the plurality of signals, a quality of the wafer.

### DETAILED DESCRIPTION

Semiconductor device manufacturing often involves tens and even hundreds of complex operations to implement raw wafer (substrate) preparation, polishing, material deposition, etching, and the like. Since even a small number of impurities or other defects introduced into processing environments during such operations can render the manufacturing products (wafers, chips, etc.) unusable for their intended purposes, various manufacturing operations are often interspersed with quality control inspections to verify adherence of intermediate and final products to specifications of the technological process being performed. Inspections can determine a degree of cleanliness of the products, presence of defects in the products, dimensions of the products, physical and chemical compositions of the products, surface morphology, and the like. The ability to produce clean wafers of high quality has multiple benefits. On one hand, high-quality bare wafers are prerequisites for high-quality final products, which can include patterned/etched wafers, wafers with films deposited thereon, and the like. On the other hand, high-quality bare wafers can be used as probes for verification of adherence of various processing operations (e.g., physical vapor deposition, chemical vapor deposition, etching, and so on) to technological specifications. The use of such wafers as probes enables identification of contamination sources as well as sources of mechanical damage and/or deformation without using more expensive wafers at advanced processing stages as probes.

Optical (including UV) inspection systems are capable of efficiently detecting impurities, lattice/morphology defects, surface roughness, and/or other product imperfections. Optical inspection systems can deploy bright-field inspection techniques (which use specular reflections of probe light from wafers), dark-field inspection techniques (that use diffusive scattering of probe light), and/or a combination thereof. A wafer (with or without a film of materials deposited thereon) can be temporarily removed from a processing line and scanned, location by location, using an optical inspection system that includes an illumination subsystem, a light collection subsystem, various additional optical elements, polarizers, field stops, a light detection subsystem, a data processing subsystem, and the like. An optical inspection system typically deploys a single inspection head with a limited field of view. As a result, inspecting a wafer of a 250-300 mm size can take tens of seconds or even longer. The speed of inspection can, therefore, be a bottleneck of the manufacturing process, especially during raw wafer manufacturing when a large number of wafers can be output almost at once, e.g., wafers cut from a single ingot.

Aspects and embodiments of the present disclosure address these and other challenges of the existing technology by providing for techniques and systems that deploy multiple inspection heads for fast inspection of wafers (and/or materials deposited thereon). Each inspection head can include a light collection subsystem that has an objective, polarizers, filters (light stops) to collect light from a desired area and/or a range of angles, and the like. Each inspection head can operate in conjunction with a light illumination subsystem equipped with optics (e.g., focusing optics, collimating optics, etc.) configured to illuminate a portion of the target with a light of desired intensity, polarization, and spatial profile. Each illumination subsystem can have one or more light sources (e.g., pulsed lasers, continuous wave lasers, etc.) configured to produce light that is subsequently delivered to the target at normal and/or oblique incidence for implementation of one or more inspection modes (e.g., bright-field inspection mode, dark-field inspection mode, double dark-field inspection mode, etc.). Each inspection head can include a light detection subsystem that detects light collected from a different portion of the target. The target can be moved relative to the inspection heads to ensure that a fast inspection of the whole target is performed with a desired resolution. Numerous additional embodiments are disclosed below. The advantages of the techniques and systems disclosed herein include, but are not limited to, the increased speed of optical inspections and the increased number of inspection modes that can be used simultaneously or sequentially for quality control of intermediate and/or final products of various manufacturing processes.

The disclosed embodiments pertain to a variety of manufacturing techniques, such as bare wafer manufacturing, chemical mechanical polishing (CMP), physical vapor deposition (PVD), chemical vapor deposition (CVD), plasma-enhanced PVD and/or CVD, atomic layer CVD, combustion CVD, catalytic CVD, evaporation deposition, molecular-beam epitaxy techniques, and so on. The disclosed embodiments can also be advantageously used to improve manufacturing techniques that use vacuum deposition chambers (e.g., ultrahigh vacuum CVD or PVD, low-pressure CVD, etc.) and/or atmospheric pressure deposition chambers.

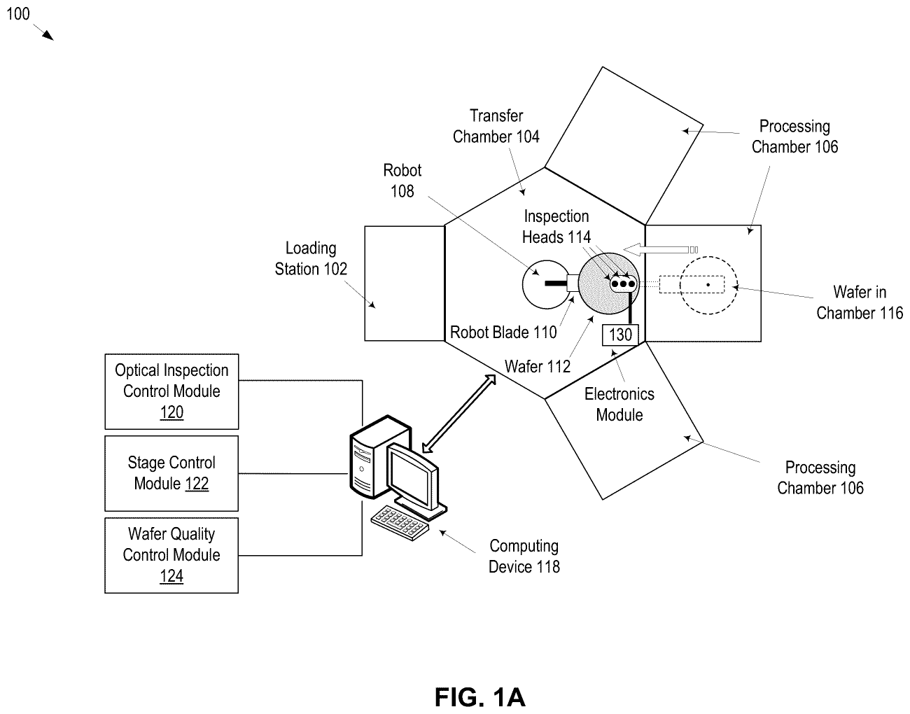

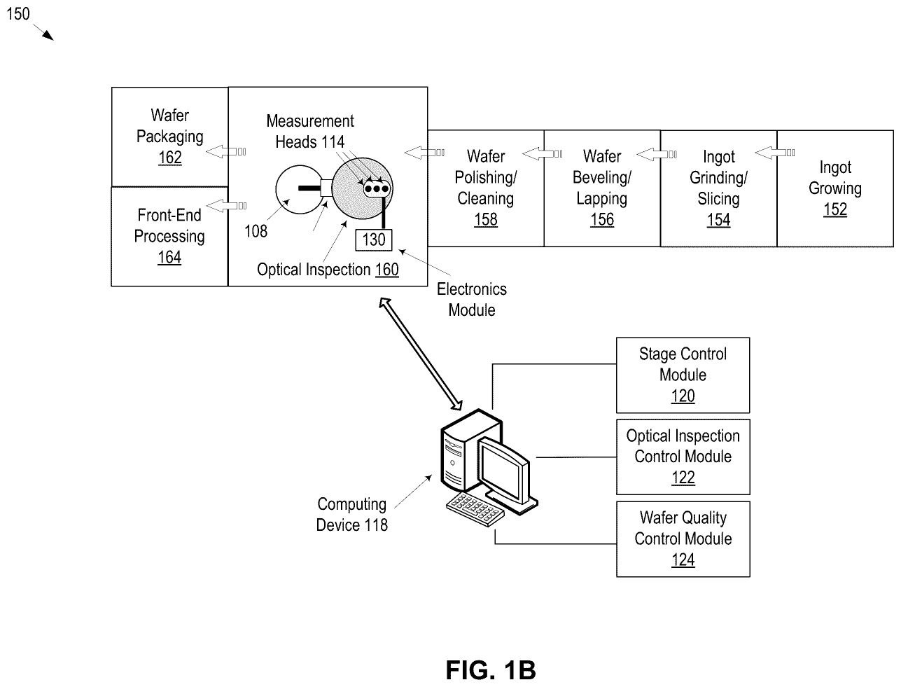

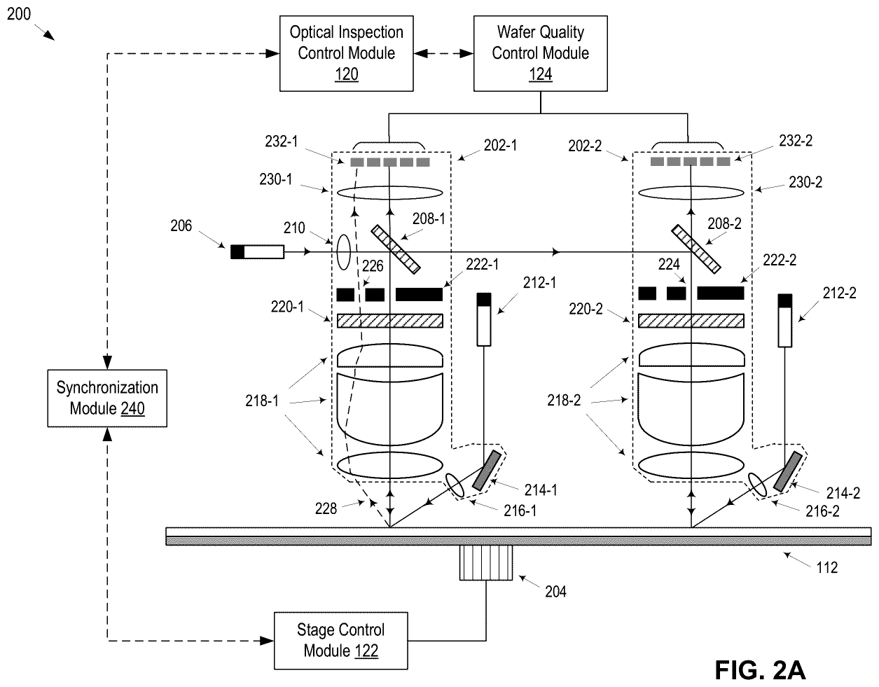

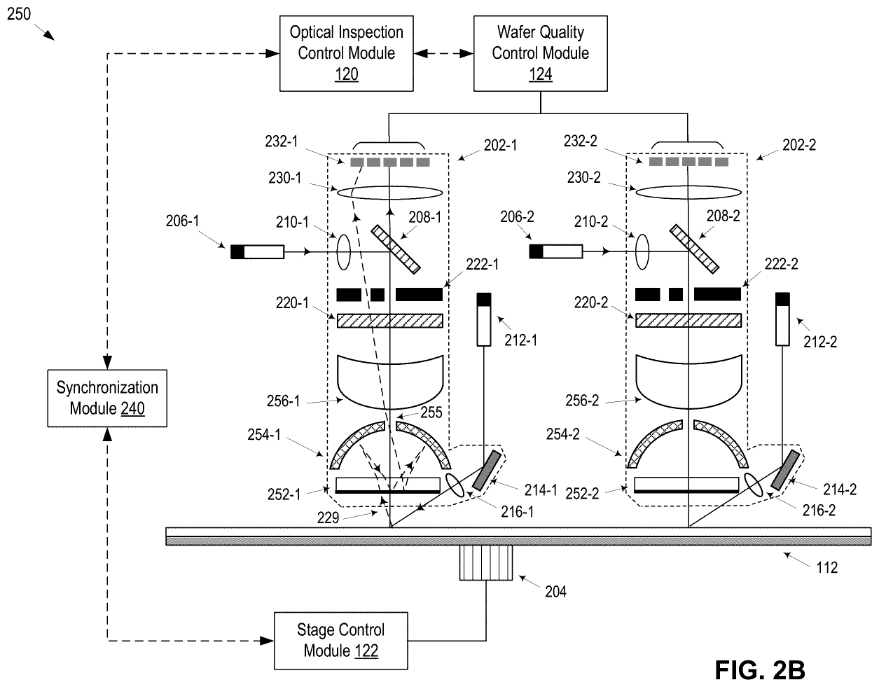

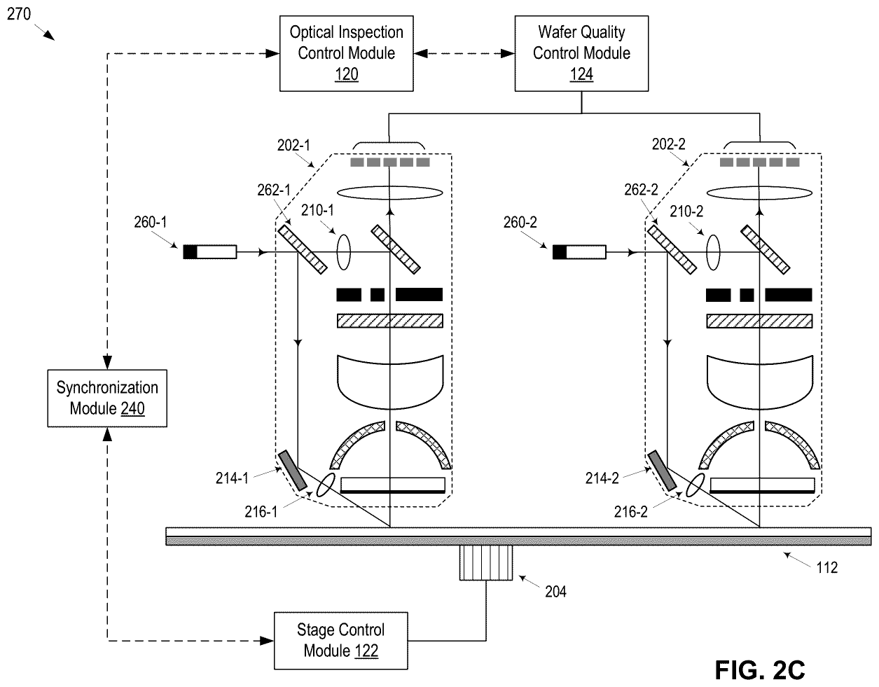

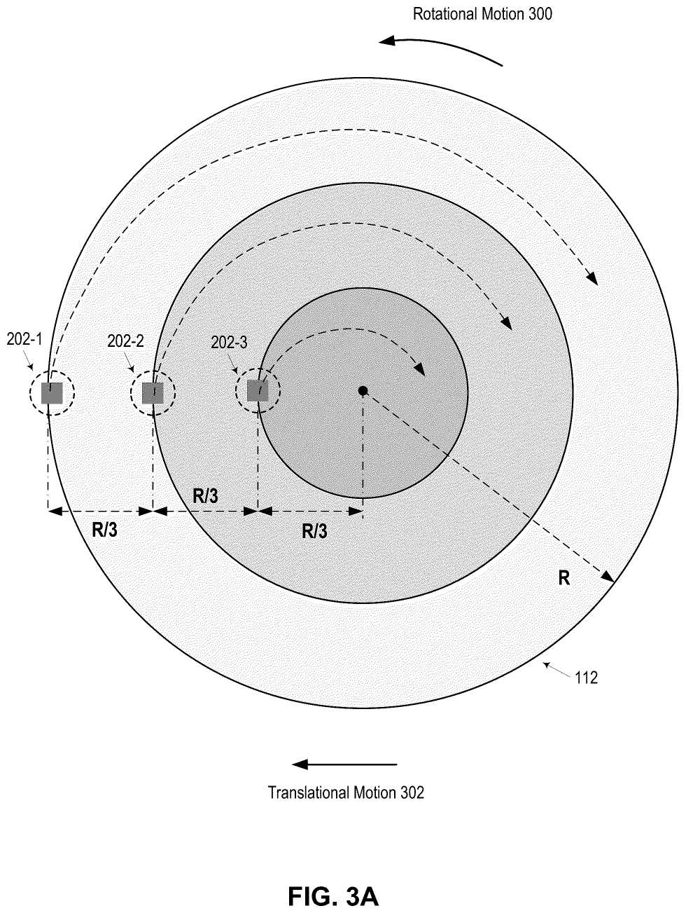

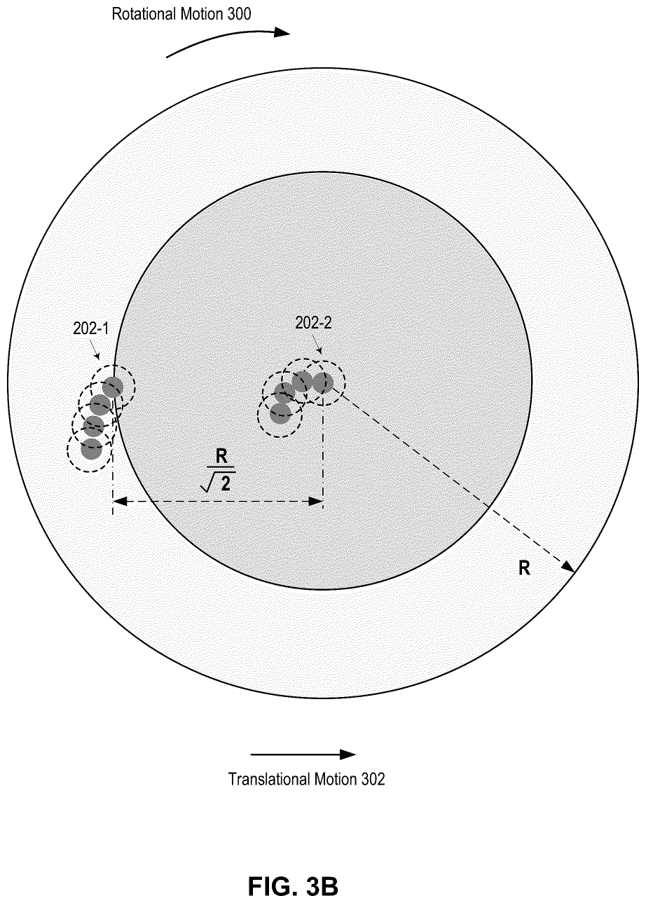

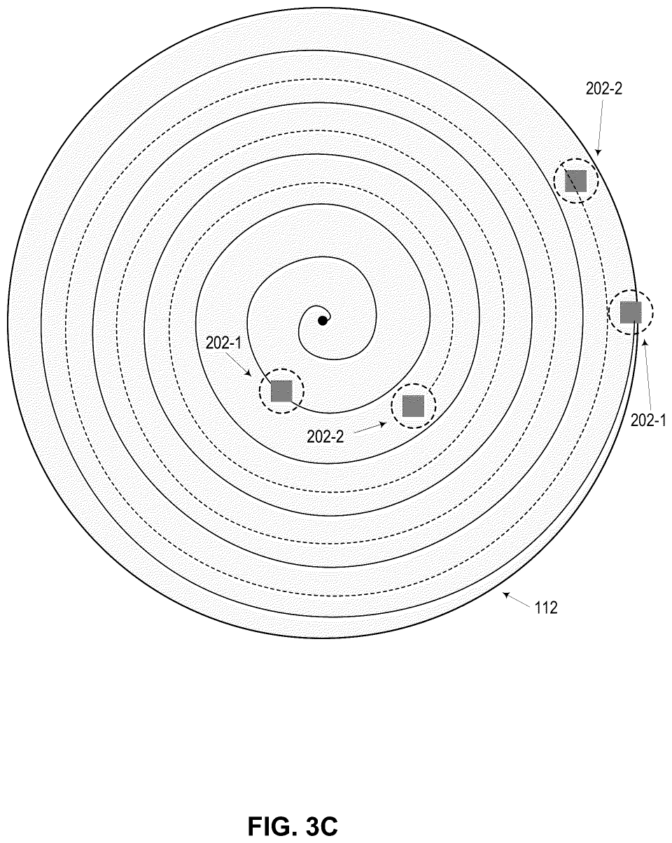

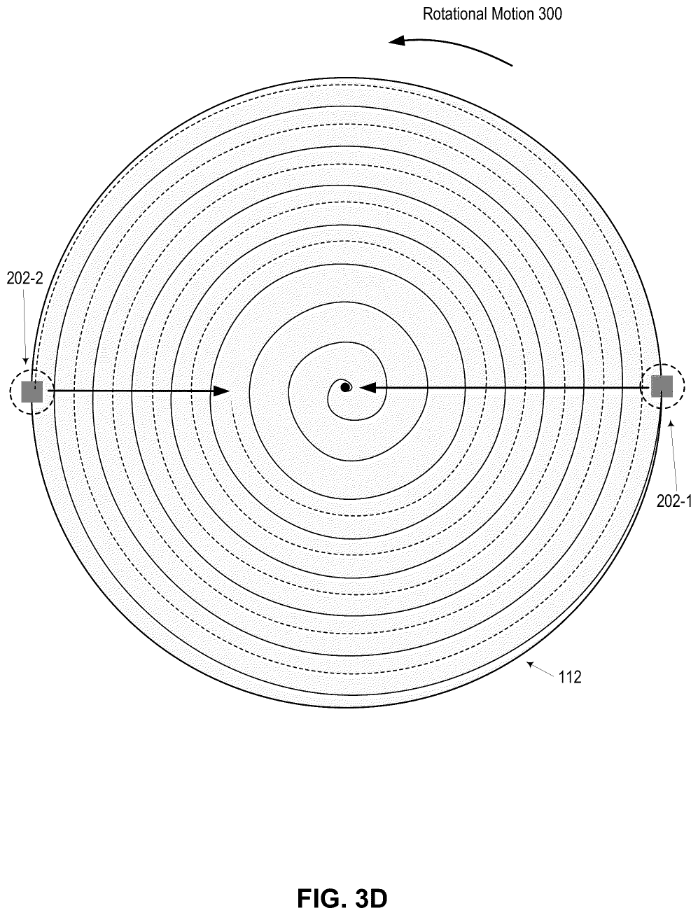

FIG. 1A illustrates an example manufacturing system 100 capable of using an inspection device with multiple inspection heads for wafer quality control during front-end wafer manufacturing, in accordance with at least one embodiment. As illustrated in FIG. 1A, manufacturing system 100 can include a loading station 102, a transfer chamber 104, and one or more processing chambers 106. Processing chamber(s) 106 can be interfaced to the transfer chamber 104 via transfer ports (not shown). The number of processing chamber(s) associated with transfer chamber 104 can vary (with three processing chambers indicated in FIG. 1A as a way of example). Transfer chamber 104 can include a robot 108 operating a robot blade 110 that supports and moves a wafer (with or without materials deposited thereon) 112, sometimes also referred to as the target herein. Multiple inspection heads 114 perform are used to perform a simultaneous optical inspection of wafer 112, as described in more detail in conjunction with FIGS. 2-3. Although inspection heads 114 are shown in FIG. 1A as being located in transfer chamber 104, in some embodiment inspection heads 114 can be located in one of processing chambers 106 or loading station 102. For example, some or all inspection heads 114 can be positioned on a movable platform, which can be transferred (e.g., by robot blade 110 or a separate dedicated stage) between transfer chamber 104, processing chamber(s) 106, loading station 102, and/or any other chamber or portion of manufacturing system 100. In some embodiment, transfer chamber 104 is held under pressure (temperature) that is higher (or lower) than the atmospheric pressure (temperature) or pressure in processing chambers 106.

Robot 108 can transfer various products and devices (e.g., semiconductor wafers, substrates, liquid crystal displays, reticles, calibration devices) between loading station 102 and one of processing chambers 106. In one embodiment, robot blade 110 of robot 108 supports wafer 112 when the latter is transferred into one of processing chambers 106 (e.g., as shown by wafer in chamber 116 position). Robot blade 110 can be attached to an extendable arm sufficient to reach between different chambers. Each inspection head 114 scans wafer 112 with one or more beams of light and collects light reflected from wafer 112. Inspection heads 114 can be configured to use visible light, UV light, and/or other electromagnetic radiation to inspect wafer 112. Robot blade 110 can deliver (and retrieve) wafer 112 to (and from) the processing chamber(s) 106 through a slit valve port (not shown) while a lid to the processing chamber(s) 106 remains closed. Processing chamber(s) 106 can contain processing gasses, plasma, and various particles used in deposition processes. A magnetic field can exist inside the processing chamber(s) 106. The inside of processing chamber(s) 106 can be held at temperatures and pressures that are different from the temperature and pressure outside the processing chamber(s) 106. Although wafer 112 is shown as being supported and moved by the robot blade 110 of robot 108, in other embodiments, wafer 112 can be transported using a dedicated motion stage or any other suitable movable stage, e.g., a polishing head or another wafer.

An electronics module 130 controls operations of inspection heads 114 and can further control at least some processing of optical inspection data collected by inspection heads 114. Electronics module 130 can include a microcontroller and a memory device (e.g., buffer) coupled to the microcontroller. The memory device can be used to store instructions that control operations of inspection heads 114 and optical inspection data before transmitting the optical inspection data to a computing device 118. Computing device 118 can include optical inspection control module 120 that selects (e.g., in response to instructions stored on computing device 118 or received from a human operator of manufacturing system 100) modes of inspection, resolution of inspection, wavelengths used by inspection heads 114, inspection frequency (e.g., pulsed light source repetition rate), zoom of objectives, and the like. Computing device 118 can further include a stage control module 122 that controls speed and timing of rotational and/or translational motion of wafer 112 relative to inspection heads 114. Computing device 118 can also include a wafer quality control module 124 that processes optical inspection data collected by inspection heads 114 and determines physical/chemical composition of wafer 112, e.g., an amount of impurities, surface imperfections, pattern defects, variations in thickness, and the like. Wafer quality control module 124 can compare the obtained morphological, physical, chemical, etc., properties of wafer 112 with specifications of the manufacturing process being performed and determine adherence of wafer 112 to those specifications. Wafer quality control module 124 can then select whether the manufacturing process is to be continued or stopped, whether wafer 112 is to be removed from the processing line, returned to the processing line for further processing (e.g., additional polishing, deposition, cleaning, etc.), whether a warning or an alarm signal is to be output to the operator, or can take any number of other programmed actions.

FIG. 1B illustrates schematically an example manufacturing line 150 that performs bare wafer manufacturing and uses an optical inspection device with multiple inspection heads for wafer quality control, in accordance with at least one embodiment. As illustrated in FIG. 1B, manufacturing line 150 can include an ingot growing stage 152, which grows silicon ingots from melted silicon nuggets, and an ingot grinding/slicing stage 154, which grinds the ingots into cylinders of desired radius and cuts the cylinders into circular wafers of approximately desired thickness (e.g., in the millimeter range of thicknesses). Manufacturing line 150 can further include wafer beveling/lapping stage 156, which rounds the edges of the wafers and mechanically polishes the wafers. Manufacturing line 150 can also include wafer polishing/cleaning stage 158, which chemically polishes the wafers and removes impurities residing on the wafer's surface. Cleaned wafers can be delivered to an optical inspection stage 160 that deploys inspection heads 114 for an optical inspection of the wafers, which can be performed similarly to the optical inspection of wafers performed in conjunction with manufacturing system 100 of FIG. 1A and as described in more detail below. The wafers that successfully pass the optical inspection are delivered to wafer packaging 162 where bare wafers are packaged into wafer pods. In some embodiments, the bare wafers can instead be delivered for front-end processing 164, e.g., as performed by manufacturing system 100 of FIG. 1A or a similar system. Wafers can be silicon wafers, silicon carbide wafers, or wafers made of any other suitable materials.

FIG. 2A illustrates one example multi-head optical inspection system 200, in accordance with at least one embodiment. For conciseness and ease of viewing, FIG. 2A illustrates two inspection heads 202-1 and 202-2, but any other number, e.g., three, four, etc., of inspection heads can be used in various embodiments. Inspection heads 202-1 and 202-2 can be enclosed in separate housings that are depicted schematically with the dashed lines. In some embodiments, inspection heads 202-1 and 202-2 can be enclosed in a single common housing. Optical inspection system 200 can be used to inspect wafer 112 supported by a movable stage 204 (e.g., robot blade 108 of robot 110 or some other similar movable stage). Each inspection head 202-n can include an illumination subsystem configured to generate light that is normally and/or obliquely incident on wafer 112. As depicted in FIG. 2A, the illumination subsystem can include a first light source 206 configured to generate a beam of light that is used for normal illumination of wafer 112 and facilitates the bright-field inspection mode. The light emitted by the first light source 206 can be redirected by semi-transparent mirrors 208-1 and 208-2 along the optical axes of the respective inspection heads 202-1 and 202-2. Although in FIG. 2A, a single first light source 206 provides illumination to both inspection heads 202-n, in some embodiments, inspection heads 202-1 and 202-2 can use separate light sources for normal wafer illumination. In some embodiments, the illumination subsystem can include expander optics 210 that transforms the light beam output by first light source 206 into a flood light beam. Although (for brevity) expander optics 210 is depicted in FIG. 2A as a single lens, it should be understood that more than one lens (e.g., various focusing lens, defocusing lens, collimating lens, etc.) can be included in expander optics 210. In some embodiments, expander optics 210 can have one or more reflective optical elements, e.g., curved mirror(s). Parameters of expander optics 210 can be adjustable to enable control over the size (e.g., diameter) of the illuminated spot on wafer 112, e.g., 10-50 mm. In some embodiments, the size of the illuminated spot can be larger than 50 mm or smaller than 10 mm.

The illumination subsystem can further include second light sources 212-1 and 212-2 configured to generate light that is used for oblique illumination of wafer 112. As illustrated in FIG. 2A, oblique incidence light can be directed to wafer 112 using reflective optical elements 214-1 and 214-2. In some embodiments, oblique incidence light can be a flood light processed by expander optics 216-1 and 216-2. Expander optics 216-n can be configured to illuminate a portion of wafer 112 that is adjustable in size (e.g., semi-axes of elliptical regions of wafer 112 illuminated by the obliquely-incident light). The illumination subsystem of each inspection head 202-n can further include one or more polarizing elements (not shown in FIG. 2A) configured to control polarization of the light incident on wafer 112 (e.g., a polarizing element placed in the optical path of the light beam produced by the first light source 206). The illumination subsystem of each inspection head 202-n can be capable of delivering light of adjustable intensity, e.g., by controlling the size of the illuminated spot and/or by controlling the intensity of light output by the first light sources 206-n and or light output by the second light sources 206-n.

Each inspection head 202-n can include a collection subsystem configured to collect light reflected from wafer 112. Collection subsystem of inspection head 202-n can include a corresponding objective 218-n. Objective 218-n can include one or more lenses (three lenses are shown in FIG. 2A as an example) configured to collect bright-field light reflected from wafer 112 and/or dark-field light scattered from wafer 112. The number and types of lenses of the objective 218-n can be selected, e.g., using any known techniques, to reduce light aberration in objective 218-n, including chromatic aberration. In some embodiments, each objective 218-n can have an outer diameter of 75 mm or less. Collection subsystem of inspection head 202-n can include one or more polarization filters 220-n configured to pass light of a specific target polarization, e.g. s-polarization, p-polarization, right-handed circular (or elliptic) polarization, left-handed circular (or elliptic) polarization, and so on.

Collection subsystem of inspection head 202-n can further include one or more directional filters 222-n configured to pass light collected from a particular interval of angles of reflection (or scattering) from wafer 112. Directional filters 222-n can be implemented via a light absorbing plate in which suitable apertures are cut out for the passage of light. For example, a central aperture 224 admits the normally reflected light (and allows passage of incident light from first light source 206) whereas a side aperture 226 admits scattered light (an example scattered light beam 228 is depicted schematically). In some embodiments, directional filters 222-n can be positioned at the Fourier plane of the respective objective 218-n. In some embodiments, directional filters 222-n can be positioned at some distance from the Fourier plane. For example, directional filter 222-n can be positioned at distance D∈[0.8d, 1.2d] from the last (e.g., topmost) optical element of objective 218-n, where d is the distance from that last optical element to the Fourier plane of objective 218-n. Although FIG. 2A depicts directional filters 222-n positioned farther away from objectives 218-n than the polarizing elements 220-n, in some embodiments, directional filters 222-n can be positioned closer to the corresponding objectives than the polarizing elements 220-n. In some embodiments, directional filters 222-n are characterized by adjustable numerical apertures controlled by the size of the physical apertures and/or positioning of the physical apertures relative to objectives 218-n.

Detection subsystem of each inspection head 202-n can include relay optics 230-n. Each relay optics 230-n can include one or more optical elements (e.g., lenses, mirrors, waveguides, arrays of waveguides, etc.) to deliver (e.g., focus) the reflected and scattered light on a corresponding array of light detectors 232-n. Light detectors 232-n can use complementary metal-oxide-semiconductor (CMOS) image sensors, charge-coupled devices (CCDs), hybrid CMOS-CCD image sensors, photomultiplier tubes (e.g., an array of photocathode-based pixels), photodiodes, phototransistors, or any other suitable photon detectors. Each light detector 232-n can image a separate spot on wafer 112 illuminated by the corresponding inspection column 202-n. The light intensity (e.g., reflectivity) data collected by light detectors 232-n can be provided to wafer quality control module 124 that determines the sizes/types/concentrations/locations of various defects and imperfections of wafer 112. Wafer quality control module 124 can be in communication with optical inspection control module 120 capable of changing settings of inspection heads 202-1 and/or 202-2 based on instructions from wafer quality control module 124. For example, initial inspection can be performed with a certain set resolution. When the presence of a defect is identified by wafer quality control module 124, e.g., based on light reflectivity data collected by light detector 232-1 (or 232-2, etc.), wafer quality control module 124 can output instruction to optical inspection control module 120 that can change resolution of imaging by zooming the corresponding inspection head 202-1 (or 202-2, etc.) to a specific region on the wafer 112 where the defect is located. More specifically, optical inspection control module 120 can change focal distance of objective 218-1 (or 218-2, etc.), change the distance from objective 218-1 (or 218-2, etc.) to wafer 112, and so on. Optical inspection control module 120 can additionally change numerical apertures of directional filter 222-1 (or 222-2, etc.) to facilitate a change in resolution of imaging. The inspection of the current locations of wafer 112 can be completed by each of inspection heads 202-1, 202-2 after a target amount of light is collected by each of light detectors 232-n. Subsequently, the movable stage 204 can reposition waver 112. Stage control module 122 can determine the distance and direction of repositioning of wafer 112 so that previously uninspected spots are exposed to inspection heads 202-1, 202-2, etc. Coordination between the motion of the movable stage 204 and the collection of inspection data can be facilitated by a synchronization module 240.

In some embodiments, CMOS image sensors, CCD image sensors, and/or any other images sensing elements of light detectors 232-n can operate in a time delay and integration (TDI) mode. For example, if the first light source 206 and/or second light sources 212-n are pulsed light sources (e.g., an excimer-laser pulsed laser source), each pulse can correspond to a sensing frame. In the TDI mode, each sensing pixel may aggregate electrical signals (e.g., charge signals, voltage signals, etc.) generated during multiple sensing frames. As a result, a number of low-intensity pulses can be used to achieve high imaging sensitivity and resolution without exposing wafer 112 to high-intensity beams capable of causing damage to the wafer. In those instances, where imaging is performed on a moving wafer 112 (e.g., transported by movable stage 204) the signal aggregation in the TDI mode can be performed for pixels that are sequentially exposed to the light reflected or scattered from the same region of the moving wafer 112.

In some embodiments, CMOS image sensors used in light detectors 232-n can be high-speed and low-noise sensors. For example, CMOS image sensors can have speed at or above 1 Gigapixel per second and noise at 10e or less, e.g., in the range of 2e-5e or even less, in some embodiments.

In some embodiments, some or all inspection heads 220-n can be independently configurable into one of a plurality of spectral configurations, each configuration characterized by a different wavelength of the normally-incident beam of light and/or the obliquely-incident beam of light. In some embodiments, some or all inspection heads 220-n independently configurable into one of a plurality of configurations, wherein in each of the plurality of configurations characterized by a different numerical aperture for collection of the generated light.

In some embodiments, some or all inspection heads 220-n can be independently configurable into one of a plurality of field-of-view configurations, in which the respective collection subsystem is characterized by a different numerical aperture for collection of the generated light.

In some embodiments, some or all inspection heads 220-n can be independently configurable into one of a plurality of detection configurations, in which the respective detection subsystem is characterized by at least one of a different gain, a different data rate, or a different dynamic range.

In some embodiments, some or all inspection heads 220-n may include a phase contrast function. For example, a normally-incident beam generated by one or multiple inspection heads can include polarizers that cause the normally-incident beam to be split (e.g., using Wollaston prisms) into two beams with different polarizations (e.g., an s-polarized beam and a p-polarized beam). The reflected polarized beams can then pass through the polarizers to obtain a combined beam having an interference pattern that is detected by light detectors 232-n. In some embodiments, some or all inspection heads 220-n may include a differential interference contrast (DIC) functionality where the normally-incident beam is split into two beams of different polarizations that follow close but different optical paths and probe two closely spaced locales of wafer 112.

In some embodiments, incident light (e.g., normally-incident light) can be in a polarized state, e.g., an s-polarized state or a p-polarized state, in a right-handed circularly (or elliptically) polarized state or in a left-handed circularly (or elliptically) polarized state, or in any combination thereof. In some embodiments, the collection subsystem of inspection system 200 can separately collect reflected light with different polarizations. For example, the reflected beam may pass through a polarizing optical element (e.g., a prism) so that the components of the reflected light with different polarization can be directed to different optical paths and can be detected independently. In some embodiments, polarizing elements 220-n can let one of the polarization states (e.g., s-polarized or right-handed light) of the reflected light to pass through and reject the other polarization state (e.g., p-polarized or light-handed light) of the reflected light, or vice versa. In some embodiments, polarizing elements 220-n can let through one of the polarization states of the reflected light reflected off a first region of wafer 112 and let through the other polarization state of the reflected light reflected off a second region of wafer 112.

In some embodiments, each (or some) region of wafer 112 can be imaged using two or more angles of incidence of the normally-incident and/or obliquely incident beams. The directions of the incident beams can be controlled, in some embodiments, by tilting inspection heads 202-1, 202-2 and/or some elements of inspection heads 202-1, 202-2, e.g., semi-transparent mirrors 208-1, 208-2 (to change directions of the normally-incident beams) and/or reflective optical elements 214-1 and 214-2 (to change directions of the obliquely-incident beams). Two or more images obtained by light detectors 232-n for different tilt angles can be aggregated (e.g., averaged) to reduce effects of reflection signal loss (or distortion) due to speckle artifacts.

In some embodiments, multiple images of specific regions of wafer 112 generated using inspection heads 202-1, 202-2, etc., may be fused to obtain a combined image of the region. The combined image may include multiple images obtained using one or more inspection heads 202-1, 202-2, etc., one or more angles of incidence of normally-incident light, one or more angles of incidence of obliquely-incident light, one or more resolutions, one or more sensing beam powers, and the like. In some embodiments, different images of the same region can be used to eliminate or reduce noise in the combined image of that region. Different images of the same region may provide complementary information about defects and imperfections located in those regions. In some embodiments, various defects can be classified among a plurality of classes (bins), e.g., a particle defect, a narrow contaminated area, a wide contaminated area, a hump, a groove, a wafer crack, a wafer deformation, a flaking of a film deposited on the wafer, and the like. Classification of defects among the classes can be based on the multiple images obtained by various modes (channels) of inspection heads 202-1, 202-2, etc., with different inspection modes detecting different optical features of the respective defects/imperfections.

FIG. 2B illustrates another example multi-head optical inspection system 250, in accordance with at least one embodiment. FIG. 2B illustrates two inspection heads 202-1 and 202-2 having catadioptric objectives. It should be understood that any other number, e.g., three, four, etc., of inspection heads can be used in various embodiments. More specifically, the catadioptric objective of head 202-n includes, as shown, a semi-transparent mirror plate 252-n, a focusing mirror 254-n, and one or more lens 256-n. The catadioptric objectives that use of a focusing (e.g., spherical, ellipsoid, parabolic, etc.) mirror can have an advantage of providing a wide field-of-view, e.g., with the focusing mirrors 254-n collecting scattered dark-field light (e.g. scattered light beams 229) from a large interval of angles (large numerical aperture). Catadioptric objectives can provide additional benefits of supporting different spectral distributions (e.g., wavelengths) of imaging beams without introducing detrimental dispersion to the optical paths of various reflected and scattered beams. The presence of two (or some other even number of) reflective optical elements in the catadioptric objective, e.g., the semi-transparent mirror plate 252-n and the focusing mirror 254-n, can have an advantage of preserving a relative phase of different polarizations (e.g., s-polarization and p-polarization, or different circular polarizations) present in the light collected by the objective. In some embodiments, the reflective optical elements can be additionally coated with transparent dielectric coatings (films) with the thickness determined to preserve the relative phase of different polarizations. The focusing mirrors can have an opening 255 to allow passage of the incident light, the reflected light, and the focused scattered light (an example scattered light beam 229 is depicted for illustration). Example multi-head optical inspection system 250 can deploy separate first light sources 206-1 and 206-2 (and the corresponding separate expander optics 210-1 and 210-2).

In some embodiments, instead of deploying the second light source 260-2, multi-head optical inspection system 270 can reuse the light produced by light source 260-1 and specularly reflected from wafer 112. More specifically, a portion (e.g., 90%, 80%, etc.) of the reflected light passing through directional filter 221-1 can be redirected towards expander optics 210-2 of inspection head 202-2. In some embodiments, a portion of the specularly-reflected light (bright-field channel) can be redirected. In some embodiments, a portion of the diffusively-reflected light (dark-field channel) can be redirected. In some embodiments, a portion of both the specularly-reflected light and the diffusively-reflected light can be redirected.

FIG. 2C illustrates yet another example multi-head optical inspection system 270, in accordance with at least one embodiment. FIG. 2C illustrates two inspection heads 202-1 and 202-2 with each inspection head utilizing a common light source for the bright-field (normal) illumination and dark-field (oblique) illumination, e.g., a common light source 260-1 for inspection head 202-1 and a common light source 260-2 for inspection head 202-1. A beam splitter 262-n can be used to direct a portion of light output by common light source 260-n towards mirror 214-n for dark-field illumination. The bright-field channel and the dark-field channel can have separate expander optics, e.g., expander optics 210-n for bright-field illumination and expander optics 216-n for dark-field illumination.

Numerous variations of optical inspection systems 200, 250, and 270 and techniques of use thereof are within the scope of the present disclosure. In some embodiments, optical inspections can be performed by independently operating inspection heads 202-n. For example, each inspection head 202-n can have a collection subsystem with the objective that has an independently adjustable focal distance, distance to wafer 112, directional filters 222-n, polarizing elements 220-n, and so on. In some embodiments, each inspection head 202-n can operate in a different inspection mode. For example, inspection head 202-1 can be configured to operate in the bright-field mode and inspection head 202-2 can operate in the dark-field mode. In some instances, any or each of inspection heads 202-n can operate in both the bright-field and the dark field mode simultaneously. In some embodiments, inspection head 202-1 can operate with the polarizing element 220-1 admitting a first polarization of light (e.g., s-polarization, right-handed circular polarization, etc.) and inspection head 202-2 can operate with polarizing element 220-2 admitting a second polarization of light (e.g., p-polarization, left-handed circular polarization, etc.). In some embodiments, the illumination subsystem of any of inspection heads 202-n can generate incident light that is polarized (e.g., by placing an additional polarizing element, not shown in FIG. 2A and FIG. 2B, in the optical path of the light beam produced by the first light source 206 or 206-n). Each inspection head 202-n can be configured to selectively operate in an aligned polarization state, e.g., with the incident light having a first polarization and the admitted reflected/scattered light also having the first polarization. Each inspection head 202-n can be configured to selectively operate in a cross-polarization state, e.g., with the incident light having a first polarization and the admitted reflected/scattered light having the second polarization. In some embodiments, different inspection heads 202-n can use light source(s) that generate light of different wavelengths. For example, inspection head 202-1 can use 532 nm light source(s), inspection head 202-2 can use 266 nm light source(s), inspection head 202-3 (not shown in FIGS. 2A-C) can use 193 nm light source(s), and so on.

Any of the light sources 206-n and/or 260-n can be a broadband laser, a narrow-band laser, a light-emitting diode, a semiconductor laser, a gas laser, or any other type of a laser. Any of the light sources 206-n and/or 260-n can be a continuous wave laser, a single-pulse laser, a repetitively pulsed laser, a mode locked laser, and the like. In some embodiments, any of the light sources 206-n and/or 260-n can be or (include) an excimer laser, which can be a gas laser using a combination of one or more noble gasses (such as argon, krypton, xenon, etc.) and one or more reactive halogen gasses (such as chlorine, fluorine, etc.) as the gain medium. An excimer laser can produce light in the 100-400 nm wavelength range, such as 126 nm light, 157 nm light, 193 nm light, 222 nm light, 248 nm light, 308 nm light, 351 nm light, and/or any other suitable wavelength. The excimer laser can be a pulsed laser capable of operating at a high power. In some embodiments, some or all inspection heads 202-1, 202-2, etc., may include a pulsed light source (e.g., any of light sources 206, 206-n, 214-n, 260-n) that generates light pulses of high power. In some embodiments, some or all inspection heads 202-1, 202-2, etc., may deploy a pulse stretcher that reduces the peak power of the light pulses. For example, each light pulse can be split (e.g., using one or more beam splitters) into several pulses, with each of the several pulses directed to a distinct optical path having a different delay time. The several paths can then be merged into a common optical path directed to wafer 112. As a result, a single high-power pulse is split into multiple pulses with a higher repetition rate and correspondingly reduced peak power. In some embodiments, the high-power pulses can have a peak power that exceeds 1 W. In some embodiments, the repetition rate of the high-power pulses may be in the range between 100 Hz and 30 KHz (with the pulse stretcher reducing the peak power and increasing the repetition rate proportionally to the number of split pulses).

“Light” output by light sources 206-n and 260-n should be understood as referring to any signals of electromagnetic radiation, such as beams, wave packets, pulses, sequences of pulses, or other suitable types of signals. In some embodiments, frequency of laser pulsing of any light sources 206-n and/or 260-n can be in the range of 1-100 KHz. In some embodiments, frequency of laser pulsing can be adjusted dynamically (e.g., as described in more detail below in conjunction with FIGS. 3A-C) depending on positioning of inspection heads 202-n relative to wafer 112.

FIGS. 3A-C illustrate schematically example operations of a movable stage that imparts motion to a wafer under inspection, in accordance with some embodiments. FIG. 3A depicts schematically a circular wafer 112 of radius R. FIG. 3A further depicts a radial positioning of three inspection heads 202-1, 202-2, and 202-3, with the outer circumferences of the corresponding objectives depicted with dashed circles (not to scale). The squares inside the dashed circles indicate the fields of view of the detection subsystems of the corresponding inspection heads. The inspection heads 202-1, 202-2, and 202-3 are positioned along a radius of wafer 112 spaced with distance R/3 (or R/N, if N inspection heads are deployed). At the beginning of inspection of wafer 112, inspection head 202-1 can be positioned at the outer edge of wafer 112, inspection head 202-1 can be positioned at distance 2R/3 from the center of wafer 112, and inspection head 202-3 can be positioned at distance R/3 from the center. The movable stage (e.g., robot 108 in FIGS. 1A-B) can impart a combination of a rotational motion 300 and a translational motion 302 to cause the inspection heads to scan wafer 112 in a spiral fashion, as depicted schematically with dashed arrows. As a result of rotational motion 300 and translational motion 302, each inspection head can scan an annular (or circular, in case of inspection head 202-3) portion of wafer 112. For example, inspection head 202-1 can scan the regions of wafer 112 that are located at distances d∈[2R/3, R] from the center of wafer 112; inspection head 202-2 can scan the regions of wafer 112 that are located at distances d∈[R/3, 2R/3] from the center of wafer 112; and inspection head 202-3 can scan the regions of wafer 112 that are located at distances d∈[0, R/3] from the center of wafer 112. (The portions of wafer 112 scanned by different inspection heads 202-n are indicated with different shading.)

Since each inspection head 202-n in FIG. 3A scans an equal portion of the radial distance, the areas scanned by each inspection head can be different, with inspection head 202-1 scanning the largest area and inspection head 202-3 scanning the smallest area. To accomplish scanning of each area within the same time, image acquisition rate (laser pulse rate) may be dynamically adjusted depending on the distance d between a particular inspection head 202-n and the center of wafer 112. In one example non-limiting embodiment, the size of the field of view can be a×a. Correspondingly, to fully scan a ring of thickness a and radius d, an inspection head can use at least

$$n = \frac{2 π d}{a}$$

imaging frames (each frame obtained using one or more laser pulses). If the angular velocity of rotational motion is ω, one frame has to be taken every

$$τ = \frac{2 π}{ω n} = \frac{a}{ω d}$$

seconds. Correspondingly, the frame acquisition rate

$$v ( d ) = \frac{1}{τ} = \frac{ω d}{a}$$

can be a function of the distance d, with each inspection head 202-n acquiring imaging frames faster at larger distances d and slower at smaller distances d, and with outer inspection head 202-1 acquiring imaging frames faster than inspection head 202-2, and inspection head 202-2 acquiring imaging frames faster than inspection head 202-3.

In some embodiments, each inspection head can be configured to acquire imaging frames with the same fixed frame acquisition rate and with each inspection head inspecting a region of the wafer of the same area. FIG. 3B depicts schematically a circular wafer 112 inspected by two inspections heads 202-1 and 202-2. More specifically, inspection head 202-1 can scan the regions of wafer 112 located at distances d∈[R/\sqrt{2}, R] from the center of wafer 112 and inspection head 202-2 can scan the regions of wafer 112 located at distances d∈[0, R/\sqrt{2}] from the center of wafer 112. (The portions of wafer 112 scanned by different inspection heads are indicated with different shading.) The scanning of wafer 112 can be performed with wafer 112 rotated and translated, relative to stationary inspection heads 202-1 and 202-2 in such a way that maintains each inspection head within the area assigned to the respective head, as depicted schematically with the shifting (circular) fields of view. In some embodiments, the distance between inspection heads 202-1 and 202-2 can be fixed. In some embodiments, the distance between inspection heads 202-1 and 202-2 can be dynamically adjusted during wafer inspection, to facilitate efficient (with minimal redundancy) imaging of the full area of wafer 112. In some embodiments, with the distance between inspection heads 202-n fixed, one or more of the inspection heads can remain (or move to) an area previously visited by that inspection head to allow other inspection head(s) to be repositioned to new areas. A specific algorithm that rotates and translates wafer 112 can be configured to minimize such redundant revisiting of previously inspected areas, ensure that each inspection head spends approximately the same amount of time performing redundant revisiting, and/or optimize the motion of wafer 112 in other suitable ways.

In some embodiments, each inspection head 202-n can scan the full area of wafer 112. For example, inspection head 202-1 can scan wafer 112 using the bright-field scanning mode and inspection head 202-2 can scan wafer 112 in the dark-field scanning mode. As another example, inspection head 202-1 can scan wafer 112 using a first polarization of incident (or reflected/scattered) light and inspection head 202-2 can scan wafer 112 using a second polarization of incident (or reflected/scattered) light. As yet another example, inspection head 202-1 can inspect the wafer using low-power sensing beams, e.g., to detect large defects or wide contamination areas on wafer 112, and inspection head 202-2 can scan wafer 112 with higher-power sensing beams (e.g., at or close to maximum power and sensitivity). In some embodiments, inspection head 202-2 can reduce the sensing power down when scanning a location of a wide contamination area that has been identified using inspection head 202-1.

FIG. 3C depicts schematically example operations of a movable stage with interleaved spiral wafer inspection. More specifically, during scanning of wafer 112 inspection head 202-1 can be moving (relative to wafer 112) along a solid spiral trajectory whereas inspection head 202-2 can be moving along a dashed spiral trajectory. In some embodiments, a distance between inspection head 202-1 and inspection head 202-2 remains fixed during spiral inspection. Although inspection head 202-2 is shown to be following inspection head 202-1, in some embodiments, inspection head 202-2 can be advancing ahead of inspection head 202-1. During spiral scanning, inspection head 202-1 and inspection head 202-2 can acquire images of wafer 112 synchronously or at different times. As the inspection heads approach the center of wafer 112, one of the inspection heads, e.g., inspection head 202-2, can stop taking images of wafer 112 whereas the other inspection head, e.g., inspection head 202-1, finishes the scanning of the wafer center. Although not shown explicitly in FIG. 3C, the radial step of the solid spiral may be reduced (e.g., by a factor 2) during inspection of the wafer center, to allow inspection with the same resolution as achieved with two inspection heads around the outer portions of wafer 112. In some embodiments, the distance between inspection head 202-1 and inspection head 202-2 can be made smaller, to reduce the amount of time spent on the inspection of the wafer center (and, therefore, to increase inspection throughput). In some embodiments, instead of deploying separate inspection heads 202-1 and 202-2, a common inspection head with multiple cameras mounted thereon (and positioned similarly to positions of inspection heads 202-1 and 202-2 in FIG. 3C) may be used. Although two inspection heads are illustrated in FIG. 3C, three or more inspection heads may be used for similar interleaved spiral wafer inspection (e.g., three inspection heads may be positioned along a single line or at vertices of a triangle). Although in FIG. 3C the inspection heads are moving relative to wafer 112, in embodiments, the inspection heads may remain stationary while wafer 112 is moved relative to wafer 112 so that the relative motion of the inspection heads occurs along spiral trajectories, as shown in FIG. 3C.

FIG. 3D depicts schematically example operations of wafer inspection with movable inspection heads. More specifically, during scanning of wafer 112 inspection head 202-1 can be moving as indicated with the rightward arrow whereas inspection head 202-2 can be moving as indicated with the leftward arrow. Simultaneously, wafer 112 can be performing rotational motion 300. As a result, inspection head 202-1 scans wafer 112 along the solid spiral trajectory whereas inspection head 202-2 scans wafer 112 along the dashed spiral trajectory. During spiral scanning, inspection head 202-1 and inspection head 202-2 can acquire images of wafer 112 synchronously or at different times. As the inspection heads approach the center of wafer 112, one of the inspection heads, e.g., inspection head 202-2, can stop taking images of wafer 112 whereas the other inspection head, e.g., inspection head 202-1, finishes the scanning of the wafer center. In some embodiments, one of the inspection heads, e.g., inspection head 202-1, can be stationary, while the center of wafer 112 moves towards inspection head 202-1 with some velocity v whereas inspection head 202-2 moves towards inspection head 202-1 with even higher velocity, e.g., 2v. In some embodiments, N>2 inspection heads can be used in the configuration of FIG. 3D (or FIG. 3C). The inspection heads can be evenly spaced around the circumference of wafer 112 and move toward the wafer center as wafer 112 rotates. spins. In some embodiments, one of the inspection heads can remain stationary whereas N−1 inspection heads and wafer 112 can move towards the stationary inspection head.

In some implementations disclosed above, e.g., in example operations disclosed in conjunction with FIG. 3C and/or FIG. 3D separate inspection heads may be used to scan the full area of wafer 112 using different inspection modes. For example, inspection head 202-1 may operate using one resolution, inspection wavelength(s), polarization, numerical aperture, and the like, whereas inspection head 202-2 may operate using a different resolution, inspection wavelength(s), polarization, numerical aperture, and the like. In such multi-mode inspection, both inspection heads may inspect the center part of wafer 112 (with the additional overhead of the multi-mode inspection amounting to the time the additional inspection head spends inspecting the central region of wafer 112, compared with operations of FIG. 3C and/or FIG. 3D).

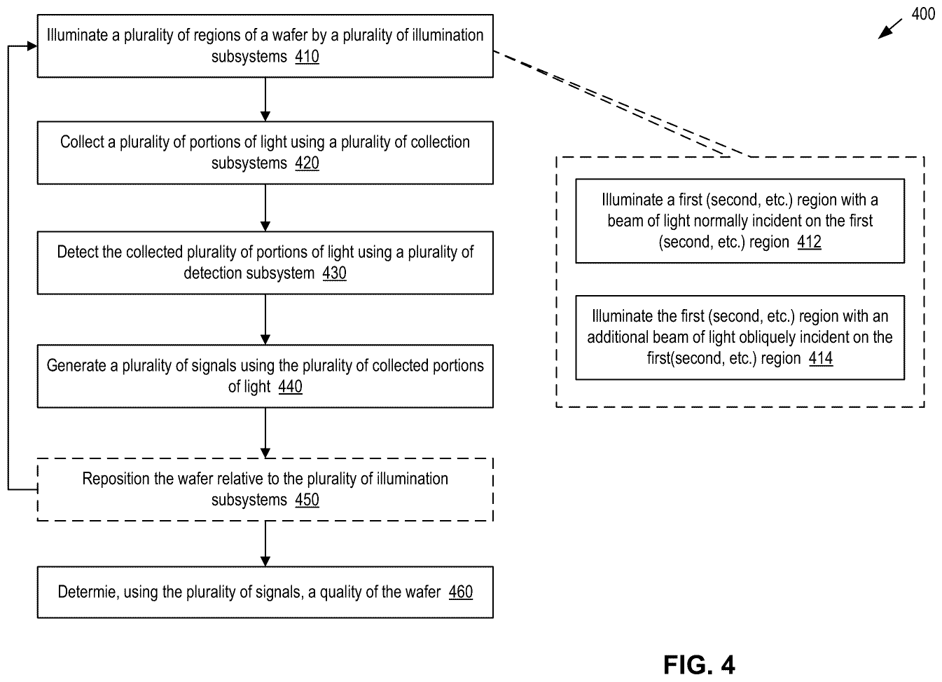

FIG. 4 is a flow diagram of an example method 400 of optical inspection of a wafer performed using multi-head inspection apparatus, in accordance with at least one embodiment. Method 400 can be performed using systems and components shown in FIGS. 2A-C or some combination thereof. Some or all blocks of method 400 can be performed responsive to instructions from computing device 118 and/or electronics module 130. Computing device 118 and/or electronics module 130 can include one or more processing devices, such as central processing units (CPUs), application-specific integrated circuits (ASICs), field programmable gate arrays (FPGAs), digital signal processors (DSPs), network processors, or the like. The processing device(s) is (are) communicatively coupled to one or more memory devices, such as read-only memory (ROM), flash memory, static memory, dynamic random access memory (DRAM), and the like. In some embodiments, computing device 118 and/or electronics module 130 can be connected to a larger network of computing devices. In some embodiments, method 400 can be performed while the wafer is still positioned inside a processing chamber. In some embodiments, method 400 can be implemented once the wafer has been removed from the processing chamber. The inspection process can occur at low temperatures, or at temperatures that are less or significantly less than the room temperature. Alternatively, the inspection process can occur at room temperature, above room temperature, or significantly above room temperature. In some embodiments, during the inspection process, the wafer can experience pressure that is less than the atmospheric pressure, including low vacuum or high vacuum conditions.

Method 400 can be performed using a plurality of inspection heads (e.g., inspection heads 202-n in FIGS. 2A-C). Each of the plurality of inspection heads can be configured to inspect (e.g., concurrently or at different times) a separate region of a plurality of regions of the wafer. Each of the plurality of inspection heads can include an illumination subsystem, a collection subsystem, and a detection subsystem. At block 410, method 400 can include illuminating the plurality of regions of the wafer. Each region of the plurality of regions can be illuminated by a respective illumination subsystem of the plurality of illumination subsystems. Each illumination subsystem can include one or more light sources, one or more collimating and/or focusing optical elements (e.g., lenses and/or curved mirrors), one or more polarizing elements, one or more beam splitters and the like.

As depicted schematically with the callout portion of FIG. 4, illuminating the plurality of regions of the wafer can include, at block 412, illuminating a first (second, third, etc.) region of the plurality of regions with a beam of light. The term “light” should be understood as including electromagnetic waves in the visible range of wavelengths, in the UV (ultraviolet) range of wavelengths, in the IR (infrared) range of wavelengths, or in any other suitable range of wavelengths. The beam of light can be normally incident on the first (second, third, etc.) region, e.g., at an angle of incidence not exceeding 10 degrees. The beam of light can be generated by a first (second, third, etc.) illumination subsystem of the plurality of illumination subsystems.

At block 414, illuminating the plurality of regions of the wafer can include illuminating the first (second, third, etc.) region with an additional beam of light. The additional beam of light can be obliquely incident on the first (second, third, etc.) region of the wafer at an angle of incidence exceeding 45 degrees. The additional beam of light can likewise be generated by the first (second, third, etc.) illumination subsystem. For example, the beam of light of the first (second, etc.) illumination subsystem can be generated by first light source 206-1 (206-2, etc.) and the additional beam of the first (second, etc.) illumination subsystem can be generated by second light source 212-1 (212-2, etc.). In some instances, any of the illumination subsystems can illuminate the wafer with only the normally incident beam of light, with only the obliquely incident beam of light, or with both the normally incident beam of light and the obliquely incident beam of light. In some implementations, one illumination subsystem can be configured to inspect a region of the wafer with a normally incident beam of light (e.g., a light with an angle of incidence not exceeding 10 degrees) and another illumination subsystem (e.g., of a different inspection head) can be configured to illuminate (concurrently or at a different time) the same target region with an obliquely incident beam of light (e.g., a beam with an angle of incidence exceeding 45 degrees). It should be understood that “first” and “second” are mere identifiers here and do not presuppose any temporal or logical order, e.g., incidence of the first beam of light may occur before, concurrently, or after incidence of the second beam.

In some embodiments, each illumination subsystem can include one or more pulsed lasers configured to generate the beam of light and/or the additional beam of light. For example, any of the first light source 206-n and/or second light source 212-n can be or include a pulsed laser. In some embodiments, the pulsed laser can include an excimer gain medium, e.g., a mixture of one or more inert gasses with one or more halogen gasses. In some embodiments, each illumination subsystem can include one or more continuous wave lasers. For example, any of the first light source 206-n and/or second light source 212-n can be a continuous wave laser.

In some embodiments, each illumination subsystem can be independently configurable into a plurality of beam size configurations, each of the plurality of beam size configurations characterized by a different size of the illuminated region of the wafer. For example, parameters of expander optics 210 in FIG. 2A, expander optics 210-n in FIGS. 2B-C, and/or expander optics 216-n in FIGS. 2A-C can be changed to increase or decrease the diameter of the flood beam(s) that illuminates wafer 112. In some embodiments, the size of the illuminated region can be changed continuously. In some embodiments, the size of the illuminated region can be selected from a discrete predetermined set of sizes.

In some embodiments, each illumination subsystem can be independently configurable into one of a plurality of intensity configurations, each of the plurality of intensity configurations characterized by a different intensity of the first and/or additional beams of light. For example, the intensity of the incident beam(s) can be controlled by changing the diameter of the flood beam(s) that illuminates wafer 112. In some embodiments, the intensity of the incident beam(s) can be controlled by adjusting settings of the light sources that generate the incident beam(s), e.g., light sources 206 and 212-n in FIG. 2A, light sources 206-n and 212-n in FIG. 2B, and/or light sources 260-n in FIG. 2C. In some embodiments, the intensity of a pulsed incident beam can be controlled by a pulse splitter. For example, a set of beam splitters can be used to direct the light generated by a light source along a plurality of optical paths, with at least some of the paths directed through a delay line with a different delay time. As a result, a single high-intensity pulse can be split into a sequence of faster-cadence but lower-intensity pulses. In some embodiments, the intensity of the incident beam(s) can be changed continuously. In some embodiments, the intensity of the incident beam(s) can be selected from a discrete predetermined set of intensities.

In some embodiments, each illumination subsystem can be independently configurable into one of a plurality of polarization configurations, each of the plurality of polarization configurations characterized by a different polarization state of the first and/or additional beams of light. “Polarization state” should be understood as including an s-polarized state of light, a p-polarized state of light, a right-handed circularly (or elliptically) polarized state of light, left-handed circularly (or elliptically) polarized state of light, or any combination (superposition) thereof. “Polarization state” should also include unpolarized light or partially-polarized light.

At block 420, method 400 can continue with collecting a plurality of portions of light. Each of the plurality of portions of light can be collected by a respective collection subsystem of a plurality of collection subsystems. Each collection subsystem can include an objective having one or more lenses and/or one or more curved mirrors, one or more polarizing elements, one or more directional filters, beam splitters, elements of relay optics, and the like. Some of the components of the collection subsystem(s) can be shared with the illumination subsystem(s), e.g., objective, beam splitters, polarizers, and so on.

Each collection subsystem can operate independently from other collection subsystems and can be configured to collect a portion of light generated upon interaction of the beam (e.g., normally-incident beam or obliquely-incident beam) with the corresponding region of the wafer. The generated light should be understood as including specularly reflected light and/or diffusely reflected (scattered) light. Each collection subsystem collects a portion of the generated light since at least some of the generated light escapes along directions that are not covered by the objective of the collection subsystem.

In some embodiments, each collection subsystem can be independently configurable into one of a plurality of size configurations. In each of the plurality of size configurations, the collected portion of the generated light can be collected from a differently-sized portion (area) of the illuminated region of the wafer. For example, changing the collected portion can be performed by changing the size of the central aperture 224 and/or side aperture 226 of directional filter 222-n, as depicted in FIG. 2A.

In some embodiments, each collection subsystem can be independently configurable into one of a plurality of directional configurations. In each of the plurality of directional configurations, the portion of the generated light can be collected from a different set of spatial directions. For example, changing the collected portion can be performed by moving side aperture 226 of directional filter 222-n to a different position relative to the optical axis of the collection subsystem (or replacing directional filter 221-n with another filter with differently-positioned side aperture 226).

In some embodiments, each collection subsystem can be independently configurable into one of a plurality of polarization configurations. In each of the plurality of polarization configurations, the collected portion of the generated light can have a different polarization. For example, polarization of the collected portion can be controlled by polarizing elements 222-n.

At block 430, method 400 can continue with detecting the collected plurality of portions of light. Each collected portion of light of the plurality of collected portions of light can be detected by a respective detection subsystem of the plurality of detection subsystems. Each light detection subsystem can include an array of light detectors, e.g. light detectors 232-n. In some embodiments, an array of light detectors can include a charge-coupling camera device. In some embodiments, an array of light detectors can include an array of photomultiplier tubes.

At block 440, method 400 can include generating a plurality of signals (e.g., electrical signals) representative of a state of the corresponding region of the wafer. Each signal of the plurality of signals can be generated using a respective collected portion of light of the plurality of collected portions of light.

At block 450, method 400 can include repositioning, using a movable stage, the wafer relative to the plurality of inspection heads. In some embodiments, repositioning the wafer can include imparting to the wafer a combination of a translational motion and a rotational motion, e.g., as described in relation to FIGS. 3A-C. As indicated with the dashed arrow in FIG. 4, after repositioning of the wafer, the operations of blocks 410-440 can be repeated for the new regions of the wafer exposed to the inspection heads.

At block 460 method 400 can include determining, using the plurality of generated signals, a quality of the wafer. For example, a processing device can process the plurality of generated signals and determine locations, types, amounts, etc., of various defects and imperfections that are present on the surface of the wafer or in the bulk of the wafer. The processing device can then determine whether the detected defects and imperfections place the wafer outside specifications of the technological process being performed or if the wafer comports to the specifications.

In some embodiments, optical inspection of the wafer can be performed with beams having different powers. For example, the beam of light generated by a first inspection head can have a reduced power compared with the beam generated by a second inspection head. The optical inspection data obtained using the first inspection head can be used to locate a contaminated region of the wafer. The processing device performing evaluation of the optical inspection data (collected with the beam of light of the first inspection head) may determine whether the contaminated region meets a threshold condition. For example, the threshold condition can include one or more of (i) a presence of one or more cracks of the wafer within the contaminated region, (ii) a presence of one or more film flakes within the contaminated region, or (iii) an area of the contaminated region exceeding a threshold (predetermined) area. Responsive to the contaminated region meeting the threshold condition, the processing device may cause a more accurate inspection of the contaminated region to be performed using the beam of light of the first inspection head having an adjusted (e.g., increased) power, or using the beam of light of the second inspection head.

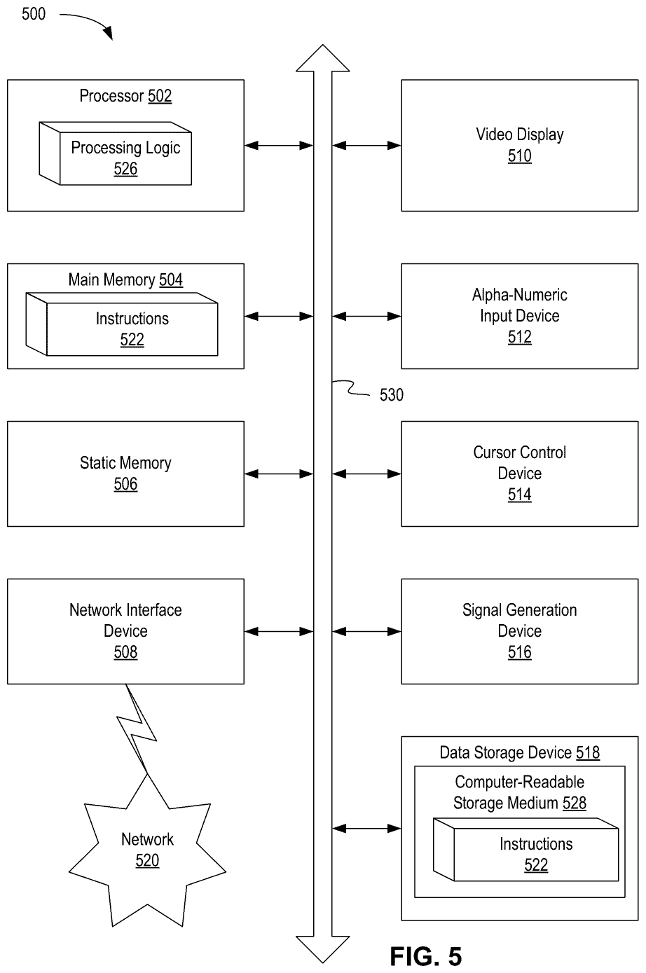

FIG. 5 depicts a block diagram of an example computing device 500 operating in accordance with one or more aspects of the present disclosure. The computing device 500 may be computing device 118 of FIGS. 1A-B. Example computing device 500 may be connected to other processing devices in a local area network (LAN), an intranet, an extranet, and/or the Internet. The computing device 500 may be a personal computer (PC), a set-top box (STB), a server, a network router, switch or bridge, or any device capable of executing a set of instructions (sequential or otherwise) that specify actions to be taken by that device. Further, while only a single example processing device is illustrated, the term “processing device” shall also be taken to include any collection of processing devices (e.g., computers) that individually or jointly execute a set (or multiple sets) of instructions to perform any one or more of the methods discussed herein.

Example computing device 500 may include a processor 502 (e.g., a CPU), a main memory 504 (e.g., read-only memory (ROM), flash memory, dynamic random access memory (DRAM) such as synchronous DRAM (SDRAM), etc.), a static memory 506 (e.g., flash memory, static random access memory (SRAM), etc.), and a secondary memory (e.g., a data storage device 518), which may communicate with each other via a bus 530. Processor 502 may include a processing logic 526 capable of executing instructions 522.

Processor 502 represents one or more general-purpose processing devices such as a microprocessor, central processing unit, or the like. More particularly, processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 502 may also be one or more special-purpose processing devices such as an application specific integrated circuit (ASIC), a field programmable gate array (FPGA), a digital signal processor (DSP), network processor, or the like. In accordance with one or more aspects of the present disclosure, processor 502 may be configured to execute instructions implementing method 400 of optical inspection of a wafer performed using multi-head inspection apparatus.

Example computing device 500 may further comprise a network interface device 508, which may be communicatively coupled to a network 520. Example computing device 500 may further comprise a video display 510 (e.g., a liquid crystal display (LCD), a touch screen, or a cathode ray tube (CRT)), an alphanumeric input device 512 (e.g., a keyboard), an input control device 514 (e.g., a cursor control device, a touch-screen control device, a mouse), and a signal generation device 516 (e.g., an acoustic speaker).

Data storage device 518 may include a computer-readable storage medium (or, more specifically, a non-transitory computer-readable storage medium) 528 on which is stored one or more sets of executable instructions 522. In accordance with one or more aspects of the present disclosure, executable instructions 522 may comprise executable instructions implementing method 400 of optical inspection of a wafer performed using multi-head inspection apparatus.

Executable instructions 522 may also reside, completely or at least partially, within main memory 504 and/or within processor 502 during execution thereof by example computing device 500, main memory 504 and processor 502 also constituting computer-readable storage media. Executable instructions 522 may further be transmitted or received over a network via network interface device 508.

While the computer-readable storage medium 528 is shown in FIG. 5 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

It should be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

The embodiments of methods, hardware, software, firmware or code set forth above may be implemented via instructions or code stored on a machine-accessible, machine readable, computer accessible, or computer readable medium which are executable by a processing element. “Memory” includes any mechanism that provides (i.e., stores and/or transmits) information in a form readable by a machine, such as a computer or electronic system. For example, “memory” includes random-access memory (RAM), such as static RAM (SRAM) or dynamic RAM (DRAM); ROM; magnetic or optical storage medium; flash memory devices; electrical storage devices; optical storage devices; acoustical storage devices, and any type of tangible machine-readable medium suitable for storing or transmitting electronic instructions or information in a form readable by a machine (e.g., a computer).

Reference throughout this specification to “one embodiment” or “an embodiment” means that a particular feature, structure, or characteristic described in connection with the embodiment is included in at least one embodiment of the disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment, embodiment, and/or other exemplarily language does not necessarily refer to the same embodiment or the same example, but may refer to different and distinct embodiments, as well as potentially the same embodiment.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an implementation” or “one implementation” or “an implementation” or “one implementation” throughout is not intended to mean the same implementation or implementation unless described as such. Also, the terms “first,” “second,” “third,” “fourth,” etc. as used herein are meant as labels to distinguish among different elements and may not necessarily have an ordinal meaning according to their numerical designation.

What is claimed is:

1. A wafer inspection system comprising:
a plurality of inspection heads, wherein each of the plurality of inspection heads is configured to inspect a corresponding region of a plurality of regions of a wafer, and wherein each of the plurality of inspection heads comprises:
an illumination subsystem configured to illuminate, with a beam of light, a corresponding region of the wafer;
a collection subsystem configured to collect a portion of light generated upon interaction of the beam of light with the corresponding region of the wafer; and
a light detection subsystem configured to detect the collected light and generate one or more signals representative of a state of the corresponding region of the wafer; and
a processing device configured to determine, using the one or more signals received from each of the plurality of inspection heads, a quality of the wafer.

2. The wafer inspection system of claim 1, wherein the beam of light comprises one of:
(i) a beam of light normally incident on the corresponding region of the wafer at an angle of incidence not exceeding 10 degrees, or
(ii) a beam of light obliquely incident on the corresponding region of the wafer at the angle of incidence exceeding 45 degrees.

3. The wafer inspection system of claim 2, wherein each illumination subsystem is further configured to illuminate the corresponding region of the wafer with an additional beam of light, wherein the additional beam of light comprises the other one of:
(i) a beam of light normally incident on the corresponding region of the wafer at an angle of incidence not exceeding 10 degrees, or
(ii) a beam of light obliquely incident on the corresponding region of the wafer at the angle of incidence exceeding 45 degrees.

4. The wafer inspection system of claim 3, wherein each illumination subsystem comprises:
a first light source to generate the beam of light; and
a second light source to generate the additional beam of light.

5. The wafer inspection system of claim 1, wherein each illumination subsystem comprises at least one of:
a pulsed laser configured to generate the beam of light, or
a continuous wave laser configured to generate the beam of light.

6. The wafer inspection system of claim 5, wherein the pulsed laser comprises an excimer gain medium.

7. The wafer inspection system of claim 1, wherein the beam of light of a first inspection head of the plurality of inspection heads comprises a pulsed beam of light, and wherein the first illumination subsystem comprises a pulse stretcher configured to reduce a peak power of the beam of light.

8. The wafer inspection system of claim 1, wherein at least one illumination subsystem is independently configurable into a plurality of configurations, wherein each of the plurality of configurations is characterized by one or more of:
a different size of the illuminated region of the wafer,
a different intensity of the beam of light,
a different polarization state of the beam of light, or
a different wavelength of the beam of light.

9. The wafer inspection system of claim 1, wherein each collection subsystem is independently configurable into one of a plurality of configurations, wherein each of the plurality of configurations is characterized by one or more of:
a differently-sized area of the illuminated region of the wafer from which the collected portion of the generated light is collected,
a different numerical aperture for collection of the generated light, or
a different polarization state of the collected portion of the generated light.

10. The wafer inspection system of claim 1, wherein at least one light detection subsystem is independently configurable into one of a plurality of configurations, wherein in each of the plurality of configurations, a respective light detection system is characterized by at least one of:
a different gain,
a different data rate,
or a different dynamic range.

11. The wafer inspection system of claim 1, wherein the beam of light of a first inspection head of the plurality of inspection heads has a reduced power compared with the beam of light of a second inspection head of the plurality of inspection heads, and wherein the processing device is further configured to:
locate, using the beam of light of the first inspection head, a contaminated region of the wafer; and
responsive to the contaminated region meeting a threshold condition, cause inspection of the contaminated region using at least one of:
the beam of light of the first inspection head having an adjusted power, or
the beam of light of the second inspection head.

12. The wafer inspection system of claim 11, wherein the threshold condition comprises at least one of:
presence of one or more cracks of the wafer within the contaminated region,
presence of one or more film flakes within the contaminated region, or
an area of the contaminated region exceeding a threshold area.

13. The wafer inspection system of claim 1, further comprising:
a movable stage supporting a wafer, wherein the movable stage is configured to reposition the wafer relative to the plurality of inspection heads.

14. The wafer inspection system of claim 13, wherein the movable stage is further configured to impart to the wafer a combination of a translational motion and a rotational motion.

15. The wafer inspection system of claim 1, wherein each detection subsystem comprises at least one of:
a charge-coupling camera device,
a complementary metal-oxide semiconductor camera device,
an array of photomultiplier tubes, or
a camera capable of operating in a time integration and delay mode.

16. The wafer inspection system of claim 1, wherein the illumination subsystem of a first inspection head of the plurality of inspection heads is configured to illuminate a target region of the plurality of regions of the wafer with a first beam of light incident on the target region at a first angle of incidence not exceeding 10 degrees, and wherein the illumination subsystem of a second inspection head of the plurality of inspection heads is configured to illuminate the target region with a second beam of light incident on the target region at a second angle of incidence exceeding 45 degrees.

17. A wafer inspection system comprising:
a first inspection head configured to inspect a first region of a wafer, wherein the first inspection head comprises:
a first illumination subsystem configured to illuminate the first region with
a first normally-incident light, and
a first obliquely-incident light;
a first collection subsystem configured to collect
a first reflected light, wherein the first reflected light is generated upon interaction of the first normally-incident light with the first region, and
a first scattered light, wherein the first scattered light is generated upon interaction of at least one of the first normally-incident light or the first obliquely-incident light with the first region; and
a first light detection subsystem configured to generate, using the first reflected light and the first scattered light, one or more first signals representative of a quality of the first region:
a second inspection head configured to inspect a second region of the wafer concurrently with the first inspection head inspecting the first region of the wafer, wherein the second inspection head comprises:
a second illumination subsystem configured to illuminate the second region with
a second normally-incident light, and
a second obliquely-incident light;
a second collection subsystem configured to collect
a second reflected light, wherein the second reflected light is generated upon interaction of the second normally-incident light with the second region, and
a second scattered light, wherein the second scattered light is generated upon interaction of at least one of the second normally-incident light or the second obliquely-incident light with the second region; and
a second light detection subsystem configured to generate, using the second reflected light and the second scattered light, one or more second signals representative of a quality of the second region; and
a processing device configured to determine, using the one or more first signals and the one or more second signals, a quality of the wafer.

18. A method to operate a wafer inspection system, the method comprising:
illuminating a plurality of regions of a wafer, wherein each region of the plurality of regions is illuminated by a respective illumination subsystem of a plurality of illumination subsystems;
collecting a plurality of portions of light, wherein each of the plurality of portions of light is collected by a respective collection subsystem of a plurality of collection subsystems;
detecting the collected plurality of portions of light, wherein each collected portion of light of the plurality of collected portions of light is detected by a respective detection subsystem of a plurality of detection subsystems;
generating a plurality of signals, wherein each signal of the plurality of signals is generated using a respective collected portion of light of the plurality of collected portions of light; and
determining, using the plurality of signals, a quality of the wafer.

19. The method of claim 18, wherein illuminating the plurality of regions of the wafer comprises:
illuminating a first region of the plurality of regions with a beam of light generated by a first illumination subsystem of the plurality of illumination subsystems, wherein the beam of light is normally incident on the first region at an angle of incidence not exceeding 10 degrees; and
illuminating the first region with an additional beam of light generated by the first illumination subsystem, wherein the additional beam of light is obliquely incident on the first region of the wafer at the angle of incidence exceeding 45 degrees.

20. The method of claim 19, wherein:
a spectral distribution of the beam of light is different from a spectral distribution of the additional beam of light, and/or
a polarization state of the beam of light is different from a polarization state of the additional beam of light.

21. The method of claim 18, further comprising:
repositioning, using a movable stage, the wafer relative to the plurality of illumination subsystems, wherein repositioning the wafer comprises imparting to the wafer a combination of a translational motion and a rotational motion.

22. The method of claim 18, wherein each signal of the plurality of signals is generated using a respective collected portion of light of the plurality of collected portions of light.
